(19) United States
(12) Patent Application Publication
(10) Pub. No.: US 2022/0005690 A1
(43) Pub. Date: Jan. 6, 2022

(54) METHOD OF FORMING SILICON FILM ON SUBSTRATE HAVING FINE PATTERN

(71) Applicants: TOKYO ELECTRON LIMITED, Tokyo (JP); JAPAN ADVANCED INSTITUTE OF SCIENCE AND TECHNOLOGY, Nomi-shi, Ishikawa (JP)

(72) Inventors: Yuki TANAKA, Nirasaki-shi, Yamanashi (JP); Hiroyuki HASHIMOTO, Nirasaki-shi, Yamanashi (JP); Mayuko NAKAMURA, Nirasaki-shi, Yamanashi (JP); Takashi MASUDA, Nomi-shi, Ishikawa (JP); Hideyuki TAKAGISHI, Nomi-shi, Ishikawa (JP)

(21) Appl. No.: 17/282,928

(22) PCT Filed: Oct. 11, 2019
(86) PCT No.: PCT/JP2019/040194

§ 371 Date: Apr. 5, 2021

(30) Foreign Application Priority Data
Oct. 15, 2018 (JP) 2018-194401

(51) Int. Cl. H01L 21/02

(52) U.S. Cl. CPC H01L 21/02488; H01L 21/02496; H01L 29/66545; H01L 21/02532; H01L 21/02628; H01L 21/02502

(57) ABSTRACT

A method of forming a silicon film on a substrate having a fine pattern includes performing surface treatment with an adhesion promoter on the substrate having the fine pattern, forming a coating film by applying a silane polymer solution to the substrate on which the surface treatment has been performed, and heating the coating film.

### TECHNICAL FIELD

The present disclosure relates to a method of forming a silicon film on a substrate having a fine pattern.

### BACKGROUND

Silicon, for example, amorphous silicon, is used to embed a contact hole or a line in a semiconductor integrated circuit device, and to form a thin film for forming an element or a structure. As a method of forming a silicon film, Patent Documents 1 to 3, for example, disclose a method of forming a silicon film by obtaining a silane polymer from irradiating light on a photopolymerizable silane compound, such as a cyclic silane compound, then by applying a solution obtained from dissolving the silane polymer in a solvent to a substrate to be processed, and by heating the solution.

Meanwhile, as a method of improving adhesion between a substrate to be processed and a processed film formed on a surface of the substrate to be processed, Patent Documents 4 to 7, for example, disclose a method of forming a processed film after applying a silane coupling agent to the surface of a substrate to be processed.

### PRIOR ART DOCUMENTS

### Patent Documents

(Patent Document 1) Japanese Laid-Open Patent Publication No. 2004-241751

(Patent Document 2) Japanese Laid-Open Patent Publication No. 2003-318120

(Patent Document 3) Japanese Laid-Open Patent Publication No. 2003-313299

(Patent Document 4) International Publication No. WO 2013/154075

(Patent Document 5) Japanese Laid-Open Patent Publication No. 2000-106364

(Patent Document 6) Japanese Laid-Open Patent Publication No. 9-312334

(Patent Document 7) Japanese Laid-Open Patent Publication No. 9-54440

### SUMMARY

The present disclosure provides a technique capable of forming a silicon film on a substrate having a fine pattern with good pattern-embedding property.

A method of forming a silicon film on a substrate having a fine pattern according to an aspect of the present disclosure includes performing surface treatment with an adhesion promoter on the substrate having the fine pattern, forming a coating film by applying a silane polymer solution to the substrate on which the surface treatment has been performed, and heating the coating film.

According to an aspect of the method of forming a silicon film on a substrate having a fine pattern as disclosed herein, it is possible to form a silicon film with good pattern-embedding property on a substrate having a fine pattern.

### BRIEF DESCRIPTION OF DRAWINGS

FIG. 1 illustrates examples in which silicon films are formed on substrates having fine patterns according to a conventional technique. An example (a) is an SEM photograph of a substrate (before a silicon film is formed) having a fine pattern with a pattern pitch of 52 nm, examples (b) to (d) are SEM photographs of silicon films formed on the respective substrates using three types of silane polymers having different Mw, an example (e) is an SEM photograph of a substrate (before a silicon film is formed) having a fine pattern with a pattern pitch of 64 nm, examples (f) to (h) are SEM photographs of silicon films formed on the respective substrates using three types of silane polymers having different Mws.

FIG. 2 shows examples in which silicon films were formed on substrates having fine patterns using a method according to an aspect of the present disclosure. An example (a) is an SEM photograph of a substrate (before a silicon film is formed) having a fine pattern with a pattern pitch of 52 nm, examples (b) to (d) are SEM photographs of silicon films formed by changing conditions of surface treatment by an adhesion promoter of the respective substrates and show effects of the conditions of the surface treatment by the adhesion promoter, an example (e) is an SEM photograph of a substrate (before a silicon film is formed) having a fine pattern with a pattern pitch of 64 nm, and examples (f) to (h) are SEM photographs of silicon films formed by changing conditions of surface treatment by an adhesion promoter of the respective substrates.

FIG. 3 shows examples in which silicon films were formed on substrates having fine patterns using a method according to an aspect of the present disclosure. An example (a) is an SEM photograph of a substrate (before a silicon film is formed) having a fine pattern with a pattern pitch of 52 nm, examples (b) to (d) are SEM photographs of silicon films formed on the respective substrates using three types of silane polymers having different Mws, an example (e) is an SEM photograph of a substrate (before a silicon film is formed) having a fine pattern with a pattern pitch of 64 nm, and examples (f) to (h) are SEM photographs of silicon films formed on the respective substrates using three types of silane polymers having different MWs.

FIG. 4 shows examples in which silicon films were formed on substrates having fine patterns using a method according to an aspect of the present disclosure. An example (a) is an SEM photograph of a substrate (before a silicon film is formed) having a fine pattern with a pattern pitch of 52 nm, examples (b) to (e) are SEM photographs of silicon films formed by changing the conditions of surface treatment by an adhesion promoter of the respective substrates, an example (f) is an SEM photograph of a substrate (before a silicon film is formed) having a fine pattern with a pattern pitch of 64 nm, and examples (g) to (j) are SEM photographs of silicon films formed by changing conditions of surface treatment by an adhesion promoter of the respective substrates.

FIG. 5 show examples in which silicon films were formed on substrates having fine patterns using a method according to an aspect of the present disclosure. An example (a) is an SEM photograph of a substrate (before a silicon film is formed) having a fine pattern with a pattern pitch of 52 nm, examples (b) to (d) are SEM photographs of silicon films formed on the respective substrates using three types of silane polymers having different Mws, an example (e) is an SEM photograph of a substrate (before a silicon film is formed) having a fine pattern with a pattern pitch of 64 nm, and examples (f) to (h) are SEM photographs of silicon films formed on the respective substrates using three types of silane polymers having different Mws.

### DETAILED DESCRIPTION

Hereinafter, a method of forming a silicon film on a substrate having a fine pattern disclosed in the present application (hereinafter, also simply referred to as a “silicon film forming method”) will be described in detail with reference to appropriate embodiments. In addition, the method of forming a silicon film disclosed herein is not limited by the present embodiments.

[Silicon Film Forming Method]

A silicon film forming method according to an aspect of the present disclosure includes performing, on a substrate having a fine pattern, surface treatment with an adhesion promoter (hereinafter, also referred to as a “surface treatment process”), forming a coating film by applying a silane polymer solution to the substrate on which the surface treatment has been performed (hereinafter, also referred to as an “application process”), and heating the coating film (hereinafter, also referred to as a “heating process”).

<Surface Treatment Process>

In the surface treatment process, surface treatment with an adhesion promoter is performed on a substrate having a fine pattern.

(Substrate Having Fine Pattern)

The substrate having a fine pattern is not particularly limited, as long as it has a fine pattern on the surface, and in manufacturing a semiconductor integrated circuit device, any substrate on which a silicon film is to be formed may be used. Such substrates include, for example, a silicon substrate: a glass substrate; a transparent electrode such as ITO or the like; a metal substrate of gold, silver, copper, palladium, nickel, titanium, aluminum, tungsten, or the like; a plastic substrate; and a substrate made of a composite material of the above-mentioned materials.

In an embodiment, the fine pattern refers to a pattern having a unit size of 100 nm or less (preferably 80 nm or less, 60 nm or less, 50 nm or less, 40 nm or less, 30 nm, or 20 nm or less) in at least one direction. The shape of the fine pattern is not particularly limited, and may be, for example, a line shape (a groove) or a hole shape (a hole). When the fine pattern is a groove, it is sufficient for at least one of a width and a height (depth) thereof to satisfy the above-mentioned unit size condition. When the fine pattern is a hole, it is sufficient for at least one of a representative diameter and height (depth) thereof to satisfy the above-mentioned unit size condition. Multiple fine patterns may be provided on a surface of a substrate. When multiple fine patterns are present, the shapes and dimensions thereof may be the same as or different from each other.

Regarding a substrate having a fine pattern, it is preferable for a hydroxy group or a group having a hydroxy group (e.g., a silanol group) to be present on a surface of the fine pattern exposed to an external environment. In an embodiment, at least a portion of a surface of the fine pattern exposed to the external environment is formed of silicon oxide, and the silanol group is exposed to the external environment.

In an embodiment, the fine pattern includes a groove. A width of the groove is preferably 50 nm or less, more preferably 40 nm or less, 30 nm or less, or 20 nm or less. A lower limit of the width of the groove is not particularly limited, but may typically be 5 nm or more, 10 nm or more, or the like. A height (depth) of the groove is preferably 30 nm or more, more preferably 40 nm or more, 50 nm or more, or 60 nm or more. An upper limit of the groove height (depth) may typically be 100 nm or less, 90 nm or less, or the like. A length of the groove (a length of extension) is not particularly limited, and may be appropriately determined. In an appropriate embodiment, the fine pattern includes a dummy gate pattern.

(Adhesion Promoter)

The silicon film forming method of the present disclosure is characterized in that, prior to the formation of a silicon film, surface treatment is performed with an adhesion promoter on a substrate (a substrate having a fine pattern). Accordingly, the silicon film can be formed with good pattern embedding property on the substrate having a fine pattern. According to the silicon film forming method of the present disclosure, it is possible to form a silicon film with good pattern embedding property even in a fine pattern having a narrow groove having a width of 30 nm or less or 20 nm or less.

As an adhesion promoter, a compound containing a functional group that can perform surface treatment on a substrate having a fine pattern and that contributes to the adhesion between a formed silicon film and the fine pattern may be used. In an embodiment, an adhesion promoter is a compound including (i) a functional group that contributes to bonding with a surface of a substrate having a fine pattern (particularly a surface of the fine pattern exposed to an external environment) and (ii) a functional group that contributes to bonding with a silane polymer, which is a precursor of the silicon film.

Examples of functional groups of the above-mentioned (i) may include a hydroxy group and an alkoxy group. The functional groups may include only one type of functional group, or a combination of two or more types of functional groups. Among them, an alkoxy group is preferable from the perspective of efficiently surface-treating a substrate having a fine pattern.

The alkoxy group may be linear, branched or cyclic. The number of carbon atoms of the alkoxy group is preferably 1 to 10, more preferably 1 to 6 or 1 to 4, and even more preferably 1 or 2. The adhesion promoter has preferably 1 to 3, more preferably 2 or 3 functional groups corresponding to (i) above in one molecule.

Examples of functional groups corresponding to (ii) above include a vinyl group, an amino group, an epoxy group, a mercapto group, a (meth)acrylic group, an isocyanate group, an imidazolyl group, a ureid group, a sulfide group, and an isocyanurate group. One type of functional group may be included alone, or two or more types of functional groups may be included in combination. Among them, from the perspective of forming a silicon film with much better pattern embedding property and from the perspective of effectuating an inherent advantage of using a particular solvent due to satisfactory wettability shown in relationship with a particular solvent to be described later, one or more types of functional groups selected from a group including a vinyl group, an amino group, an epoxy group, a mercapto group, a (meth)acrylic group, an isocyanate group, and an imidazolyl group are preferable, and a vinyl group or an amino group is more preferable. The adhesion promoter has, in one molecule, preferably 1 to 3, more preferably 1 or 2 of the functional groups of the above-mentioned (ii).

In an embodiment, the adhesion promoter is a silane compound represented by the following formula (1).

Si(X)ₘ₁(R¹)m₂(R²)₄₋ₘ₁₋ₘ₂ (1)

[in the formula, X represents a monovalent group including a functional group that contributes to bonding with a silane polymer,
R¹ represents a hydroxy group, an alkoxy group, or a halogen atom,
R² represents a hydrogen atom, an alkyl group, or an aryl group, and
each of m1 and m2, under the condition that the sum of m1 and m2 is 4 or less, represents integers of 1 to 3. When there are multiple Xs, they may be the same as or different from each other, when there are multiple R¹s, they may be the same as or different from each other, and when there are multiple R²s, they may be the same as or different from each other.]

A number of carbon atoms of the monovalent group represented by X is preferably 20 or less, more preferably 14 or less, and even more preferably 12 or less, 10 or less, 9 or less, 8 or less, 7 or less, or 6 or less. A lower limit of the number of carbon atoms varies depending on a functional group included in the monovalent group represented by X, but is preferably 1 or more, more preferably 2 or more or 3 or more. From the perspective of forming a silicon film with good pattern embedding property, and from the perspective of effectuating an inherent advantage of using a particular solvent due to satisfactory wettability shown in relationship with a particular solvent to be described later, as the monovalent group represented by X, a monovalent group including a functional group selected from a group including a vinyl group, an amino group, an epoxy group, a mercapto group, a (meth)acrylic group, an isocyanate group, an imidazolyl group, a ureid group, a sulfide group, and an isocyanurate group is preferable, a monovalent group including one or more types of functional groups selected from a group including a vinyl group, an amino group, an epoxy group, a mercapto group, a (meth)acrylic group, an isocyanate group, and an imidazolyl group is more preferable, and a monovalent group containing a vinyl group or an amino group is even more preferable.

Specific examples of the monovalent group represented by X may include a vinyl group, an amino C₁₋₁₀ alkyl group, an N-(amino C₁₋₁₀ alkyl)-amino C₁₋₁₀ alkyl group, an N-(phenyl)-amino C₁₋₁₀ alkyl group, an N—(C₁₋₁₀ alkylidene)-amino C₁₋₁₀ alkyl group, an (epoxy C₃₋₁₀ cycloalkyl) C₁₋₁₀ alkyl group, a glycidoxy C₁₋₁₀ alkyl group, a glycidyl C₁₋₁₀ alkyl group, a mercapto C₁₋₁₀ alkyl group, an acryloxy C₁₋₁₀ alkyl group, a methacryloxy C₁₋₁₀ alkyl group, a styryl group, an isocyanate C₁₋₁₀ alkyl group, an imidazolyl C₁₋₁₀ alkyl group, a ureid C₁₋₁₀ alkyl group, a tri(C₁₋₁₀ alkoxy)syril C₁₋₁₀ alkyl tetrasulfide C₁₋₁₀ alkyl group, and a di[tri(C₁₋₁₀ alkoxy)syril C₁₋₁₀ alkyl] isocyanurate C₁₋₁₀ alkyl group. Among them, a vinyl group, an amino C₁₋₁₀ alkyl group, an N-(amino C₁₋₁₀ alkyl)-amino C₁₋₁₀ alkyl group, an N-(phenyl)-amino C₁₋₁₀ alkyl group, an N—(C₁₋₁₀ alkylidene)-amino C₁₋₁₀ alkyl group, an (epoxy C₃₋₁₀ cycloalkyl) C₁₋₁₀ alkyl group, a glycidoxy C₁₋₁₀ alkyl group, a glycidyl C₁₋₁₀ alkyl group, a mercapto C₁₋₁₀ alkyl group, an acryloxy C₁₋₁₀ alkyl group, a methacryloxy C₁₋₁₀ alkyl group, a styryl group, an isocyanate C₁₋₁₀ alkyl group, and an imidazolyl C₁₋₁₀ alkyl group are preferable, a vinyl group, a 3-aminopropyl group, an N-(2-aminoethyl)-3-aminopropyl group, an N-(phenyl)-3-aminopropyl group, an N-(1,3-dimethyl-butylidene) aminopropyl group, a (3,4-epoxycyclohexyl) ethyl group, a glycidoxypropyl group, a glycidylpropyl group, a mercaptopropyl group, an acryloxypropyl group, a methacryloxypropyl group, a styryl group, and an isocyanate propyl group are more preferable, and a vinyl group and a 3-aminopropyl group are particularly preferable.

The alkoxy group represented by R¹ may be linear, branched, or cyclic. A number of carbon atoms of the alkoxy group is preferably 1 to 10, more preferably 1 to 6, still more preferably 1 to 4, and even more preferably 1 or 2.

Examples of halogen atoms represented by R¹ may include a fluorine atom, a chlorine atom, a bromine atom, an iodine atom, and the like, and a chlorine atom is preferable.

As R¹, from the perspective of efficiently treating a surface of a substrate having a fine pattern, an alkoxy group is preferable.

The alkyl group represented by R² may be linear, branched, or cyclic. A number of carbon atoms of the alkyl group is preferably 1 to 10, more preferably 1 to 6, and even more preferably 1 to 4.

The number of carbon atoms of the aryl group represented by R² is preferably 6 to 20, more preferably 6 to 14, and even more preferably 6 to 10.

An alkyl group is preferable as R².

In the formula (1), each of m1 and m2, under the condition that a sum of m1 and m2 is 4 or less, represents an integer of 1 to 3. Preferably, m1 is 1 or 2, and m2 is preferably 2 or 3. In an appropriate embodiment, m1 is 1 and m2 is 3.

Examples of suitable adhesion promoters may include vinyltrimethoxysilane, vinyltriethoxysilane, 3-aminopropyltrimethoxysilane. N-(phenyl)-3-aminopropyltrimethoxysilane, N-(2-aminoethyl)-3-aminopropylmethyldimethoxysilane. N-(2-aminoethyl)-3-aminopropyltrimethoxysilane, 3-triethoxysilyl-N-(1,3-dimethyl-butylidene) propylamine, 3-glycidoxypropylmethyldimethoxysilane, 3-glycidoxypropyltrimethoxysilane, 3-glycidoxypropylmethyldiethoxysilane, 3-glycidoxypropyltriethoxysilane, 3-mercaptopropylmethyldimethoxysilane, 3-mercaptopropyltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, p-styryl trimethoxysilane, 3-isocyanate propyltriethoxysilane, [3-(1-imidazolyl)propyl] trimethoxysilane, 3-ureidpropyltriethoxysilane, bis(triethoxysilylpropyl)tetrasulfide, tris(trimethoxysilylpropyl)isocyanurate, vinyltrichlorosilane, methyltrichlorosilane, phenyltrichlorosilane, dimethyldichlorosilane, vinylmethyldichlorosilane, diphenyldichlorosilane, methylphenyldichlorosilane, and divinyldichlorosilane.

One type of adhesion promoter may be used alone, or two or more types of adhesion promoters may be used in combination.

From the perspective of efficiently performing the surface treatment by a vapor deposition method, a boiling point of the adhesion promoter is preferably 300 degrees C. or lower, more preferably 280 degrees C. or lower, 260 degrees C. or lower, 240 degrees C. or lower, 220 degrees C. or lower, or 200 degrees C. or lower. A lower limit of the boiling point is not particularly limited, but from the handling perspective, the lower limit may typically be 50 degrees C. or higher, 80 degrees C. or higher, or the like. In addition, in this specification, a “boiling point” means a boiling point under atmospheric pressure.

From the same perspective, a molecular weight of the adhesion promoter is preferably 400 or less, more preferably 350 or less, 300 or less, 280 or less, 260 or less, 240 or less, 220 or less, or 200 or less. A lower limit of the molecular weight is not particularly limited, but from the handling perspective, the lower limit may typically be 100 or more, 120 or more, or the like.

(Surface Treatment with Adhesion Promoter)

The method of surface treatment with an adhesion promoter is not particularly limited, as long as a substrate having a fine pattern can be subjected to surface treatment with an adhesion promoter, and either a dry method or a wet method may be used. Examples of the surface treatment by the dry method may include a method of depositing an adhesion promoter on a substrate in a heating environment. Examples of the surface treatment by the wet method include a method of applying a solution of an adhesion promoter to a substrate and a method of immersing a substrate in a solution of an adhesion promoter. As a solvent used in the wet method, any solvent capable of dissolving the adhesion promoter may be used.

From the perspective of efficiently performing surface treatment on a substrate having a fine pattern (particularly a surface of a fine pattern exposed to an external environment), the surface treatment with an adhesion promoter is preferably performed through vapor deposition. Conditions for vapor deposition are not particularly limited, and may be appropriately determined depending on the boiling point, molecular weight, or the like of the adhesion promoter that is used. When the boiling point of the adhesion promoter is Tb (degrees C.), a temperature of surface treatment through vapor deposition may be appropriately determined from a range of, for example, (Tb−100) to (Tb+50) degrees C. A time required for surface treatment through vapor deposition is not particularly limited, but from the perspective of work efficiency, a length of time may be preferably 1 hour or less, and more preferably 30 minutes or less and 20 minutes or less. The surface treatment through vapor deposition may be carried out under normal pressure or under reduced pressure.

The surface treatment with an adhesion promoter may be performed on the surface of a fine pattern exposed to the external environment, and does not necessarily have to be performed on the entire substrate.

<Application Process>

In the application process, a silane polymer solution is applied to the surface-treated substrate so as to form a coating film.

(Silane Polymer)

The silane polymer is not particularly limited, as long as a silicon film can be formed by heating. For example, a silane polymer (preferably, poly(dihydrosilane)) produced by a conventionally known method and obtained by irradiating a photopolymerizable silane compound with light may be used. In addition, for example, a silane polymer produced by a conventionally known method and obtained by heating a thermopolymerizable silane compound may be used.

In an embodiment, the method of forming a silicon film according to an aspect of the present disclosure may include irradiating a photopolymerizable silane compound with light so as to prepare a silane polymer before the application process.

Examples of photopolymerizable silane compounds may include chain silane compounds, cyclic silane compounds, and cage silane compounds. Examples of chain silane compounds may include neopentasilane, trisilane, tetrasilane, isotetrasilane, pentasilane, hexasilane, and the like. Examples of other chain silane compounds may include, for example, 2,2,3,3-tetrasilyltetrasilane, 2,2,3,3,4,4-hexasilylpentasilane, and the like. Examples of cyclic silane compounds may include cyclic silane compounds having one cyclic silane structure such as cyclotrisilane, cyclotetrasilane, cyclopentasilane, cyclohexasilane, cycloheptasilane, and the like; cyclic silane compounds having two cyclic silane structures such as 1,1′-bicyclobutasilane, 1,1′-bicyclopentasilane, 1,1′-bicyclohexasilane, 1,1′-bicycloheptasilane, spiro [2,2] pentasilane, spiro [3,3] heptasilane, spiro [4,4] nonasilane, and the like; and silane compounds in which some or all of hydrogen atoms in the above cyclic silane compounds are replaced with silyl groups or halogen atoms. Among them, cyclic silane compounds are preferable because they have excellent photopolymerizability.

In particular, from the perspective of ease of synthesis with high purity, cyclopentasilane, cyclohexasilane, and cycloheptasilane are preferable, and cyclohexasilane is more preferable. Therefore, in an embodiment, the method of forming a silicon film according to an aspect of the present disclosure may include irradiating cyclohexasilane with light to prepare a silane polymer.

The irradiation with light may be carried out under any conventionally known conditions. For example, an irradiation wavelength may be in a range of 300 to 420 nm, and an irradiation time may be in a range of 0.1 seconds to 600 minutes.

According to the method of forming a silicon film of the present disclosure, a silicon film can be formed with good pattern embedding property by using a silane polymer having a wide range of molecular sizes. Therefore, a weight average molecular weight (Mw) of the silane polymer that is used in the application process is not particularly limited, and may be, for example, in a range of 500 to 500,000. Here, in the present specification, the “weight average molecular weight” of the silane polymer is a polystyrene-equivalent weight average molecular weight measured using gel permeation chromatography (GPC).

According to the method of forming a silicon film of the present disclosure, a silicon film can be formed from a silane polymer having a weight average molecular weight (Mw) of, for example, 5,000 or more, 10,000 or more, 20,000 or more, 30,000 or more, 50,000 or more, 70,000 or more, 80,000 or more, 90,000 or more, or 100,000 or more. From the perspective of forming the silicon film with good film forming property, an upper limit of the weight average molecular weight (Mw) of the silane polymer is preferably 450,000 or less, 400,000 or less, 350,000 or less, or 300,000 or less.

(Silane Polymer Solution)

A silane polymer solution may be prepared by dissolving the silane polymer in a solvent. The solvent is not particularly limited, as long as the silane polymer can be dissolved, but from the perspective of using a wide range of molecular sizes to form a silicon film, it is preferable to use the following particular solvents.

—First Solvent—

A first solvent contains a 6- to 8-membered monocyclic saturated carbon ring in a molecule, and has a boiling point of less than 160 degrees C. By using the first solvent, a silane polymer solution can be prepared using a silane polymer having a wide range of molecular sizes.

From the perspective of solubility of a silane polymer, particularly from the perspective of using a wide range of molecular sizes to form a silicon film, the first solvent contains preferably one 6- to 8-membered monocyclic saturated carbon ring in a molecule, more preferably one 7- or 8-membered monocyclic saturated carbon ring in a molecule.

The 6- to 8-membered monocyclic saturated carbon ring may have a substituent, as long as the solubility of a silane polymer is not hindered. The substituent is not particularly limited, and examples thereof may include an alkyl group having 1 to 4 carbon atoms (preferably 1 to 3 carbon atoms, and more preferably 1 or 2 carbon atoms). A number of substituents is not limited, and when multiple substituents are included, the substituents may be the same as or different from each other.

Examples of the first solvent include cyclohexane (81 degrees C.), cycloheptane (112 degrees C.), cyclooctane (151 degrees C.), methylcyclohexane (101 degrees C.), ethylcyclohexane (132 degrees C.), dimethylcyclohexane (120 to 130 degrees C.), n-propylcyclohexane (157 degrees C.), isopropylcyclohexane (155 degrees C.), trimethylcyclohexane (136 to 145 degrees C.), and methylethylcyclohexane (148 degrees C.) (boiling points are indicated in parentheses).

Among them, from the perspective of using a wide range of molecular sizes to form a silicon film, the first solvent is preferably a cycloalkane having 6 to 8 carbon atoms, more preferably a cycloalkane having 7 or 8 carbon atoms, and particularly preferably a cycloalkane having 8 carbon atoms. Therefore, in a particularly preferred embodiment, the first solvent is cyclooctane.

A lower limit of the boiling point of the first solvent is preferably 100 degrees C. or higher, and more preferably 110 degrees C. or higher, 120 degrees C. or higher, or 130 degrees C. or higher.

As a solvent, the first solvent may be used by itself, or may be used as a mixed solvent in combination with a second solvent to be described later.

—Second Solvent—

The second solvent contains a saturated carbon ring or a partially saturated carbon ring in a molecule, and has a boiling point of 160 degrees C. or higher. By using the second solvent in combination with the first solvent, a silicon film can be formed with good film forming property from a silane polymer having a wide range of molecular sizes. As used herein, the term “partially saturated carbon ring” refers to a carbon ring obtained by converting an arbitrary number of double bonds excluding at least one double bond among double bonds of an unsaturated carbon ring into single bonds by hydrogenation.

From the perspective of using a wide range of molecular sizes to form a silicon film, the second solvent preferably contains in a molecule one 8- to 12-membered saturated carbon ring or partially saturated carbon ring. The saturated carbon ring or partially saturated carbon ring in the combination with the first solvent, from the perspective of forming a silicon film with particularly good film forming property from a silane polymer having a wide range of molecular sizes, is preferably a polycyclic saturated carbon ring or a partially saturated carbon ring, and is more preferably a bicyclic saturated carbon ring or partially saturated carbon ring. When the second solvent contains a polycyclic partially saturated carbocyclic ring in the molecule, it is preferable for at least one ring constituting the polycyclic ring to have a saturated carbon ring structure (that is, a zero degree of unsaturation). For example, when the second solvent contains a bicyclic partially saturated carbocyclic ring in a molecule, it is preferable for one ring of the bicyclic ring to have a saturated carbon ring structure and the other ring to have an unsaturated carbon ring structure.

Among them, in the combination with the first solvent, from the perspective of forming a silicon film with particularly good film forming property from a silane polymer having a wide range of molecular sizes, the second solvent preferably contains in a molecule a polycyclic saturated carbon ring, and particularly preferably contains a bicyclic saturated carbon ring.

In the second solvent, the saturated carbon ring or the partially saturated carbon ring may have a substituent, as long as the film forming property of the silicon film is not hindered. The substituent is not particularly limited, and examples thereof may include an alkyl group having 1 to 4 carbon atoms (preferably 1 to 3 carbon atoms, and more preferably 1 or 2 carbon atoms).

A number of substituents is not limited, and when multiple substituents are included, the substituents may be the same as or different from each other.

As the second solvent, for example, decahydronaphthalene (decalin) (193 degrees C.), 1,2,3,4-tetrahydronaphthalene (tetralin) (207 degrees C.), methyldecahydronaphthalene (210 degrees C.), dimethyldecahydronaphthalene (224 degrees C.), ethyldecahydronaphthalene (226 degrees C.), and isopropyldecahydronaphthalene (241 degrees C.) may be used (boiling points are indicated in parentheses).

Among them, in the combination with the first solvent, from the perspective of forming a silicon film with particularly good film forming property from a silane polymer having a wide range of molecular sizes, the second solvent is preferably a bicycloalkane having 8 to 12 carbon atoms, more preferably a bicycloalkane having 10 to 12 carbon atoms, and particularly preferably a bicycloalkane having 10 carbon atoms. Therefore, in a particularly preferred embodiment, the second solvent is decahydronaphthalene.

From the perspective of forming a silicon film with particularly good film forming property from a silane polymer having a wide range of molecular sizes, in the mixed solvent, when a volume of the first solvent is 1, a volume of the second solvent is preferably 3 or less, more preferably 2 or less or 1 or less, and still more preferably 0.7 or less or 0.5 or less.

Even if a small amount of the second solvent is contained in the mixed solvent, it is possible to enjoy the advantage of using the mixed solvent. For example, in the mixed solvent, when the volume of the first solvent is 1, the volume of the second solvent may be 0.001 or more, preferably 0.005 or more, and more preferably 0.01 or more, 0.02 or more, or 0.03 or more. In the present specification, a volume ratio of the first solvent to the second solvent is a value calculated based on the volume of the first solvent and the volume of the second solvent at a room temperature.

A concentration of the silane polymer in the silane polymer solution (hereinafter, also simply referred to as a “solution concentration”) varies according to molecular sizes of the silane polymer, but can be adjusted within a range of, for example, 30% by volume or less. From the perspective of forming a thin silicon film, the solution concentration is preferably 20 volume % or less, more preferably 10 volume % or less, and still more preferably 5 volume % or less. Conventionally, when the solution concentration becomes low, it tends to be difficult to form a silicon film on the entire surface of a substrate. In contrast, by using the mixed solvent of the first solvent and the second solvent, even when the solution concentration is low, a silicon film can be formed on the entire surface of a substrate. Along with the advantage that a silane polymer having a large molecular size (in which case a silicon film can be formed even at a low concentration) can be used, according to an aspect of the present disclosure using such a mixed solvent, an extremely thin silicon film can be formed on the entire surface of a substrate. According to an aspect of the present disclosure using such a mixed solvent, without deterioration in the film forming property, the solution concentration can be reduced to 4 volume % or less, 3 volume % or less, or 2 volume % or less. A lower limit of the solution concentration is not particularly limited, but from the perspective of the film forming property of a silicon film, the lower limit may be typically 0.1 volume % or more, 0.3 volume % or more. 0.5 volume % or more, or the like. In the present specification, a concentration of the silane polymer in the silane polymer solution is a value calculated based on a volume of the mixed solvent and a volume of the silane polymer at a room temperature. An inherent advantage obtained by using such a mixed solvent may also be enjoyed in the silicon film forming method of the present disclosure by using a particular adhesion promoter that achieves good wettability in relation to such a particular solvent.

Further, when a silicon film is formed using a silane polymer having a relatively small molecular size (e.g., Mw of 2,000 or less or 1,000 or less), only the second solvent may be used.

The silane polymer solution may contain other components, as long as the film forming property of the silicon film is not degraded. Examples of such other components may include a dopant, a surface tension modifier, and the like. As the dopant, a known dopant conventionally used in forming an n-type or a p-type silicon film may be used. As the surface tension modifier, a conventionally known surface tension modifier such as a fluorine-based surface tension modifier, a silicon-based surface tension modifier, or the like may be used.

(Application of Silane Polymer Solution)

Examples of the method of applying a silane polymer solution to a substrate may include a spin coating method, a roll coating method, a curtain coating method, a dip coating method, a spray method, and an inkjet method. Among them, it is preferable to apply the silane polymer solution using the spin coating method from the perspective of forming a silicon film with good film forming property on a substrate.

Conditions for coating by the spin coating method are not particularly limited, and may be appropriately determined by considering a molecular size or a solution concentration of the silane polymer and a desired thickness of the silicon film. For example, a rotation number in a main spinning may be in a range of 100 to 5,000 rpm, and a rotation time may be in a range of 1 to 20 seconds.

An application amount of the silane polymer solution may be appropriately determined by considering the molecular size or solution concentration of the silane polymer, a size and structure of the substrate, the desired thickness of the silicon film, and the like. Further, when the silane polymer solution is applied twice or more, respective application amounts may be the same as or different from each other.

The application of the silane polymer solution to the substrate may be performed only once, or alternatively twice or more. Prior to formation of a silicon film, according to the method of forming a silicon film in accordance with an aspect of the present disclosure, in which surface treatment with an adhesion promoter is performed, regardless of the number of times the silane polymer solution is applied, a fine pattern of a substrate can be satisfactorily embedded with a silicon film. In addition, according to the method of forming a silicon film in accordance with an aspect of the present disclosure using a particular mixed solvent, a thin silicon film can be formed on an entire surface of a substrate by using a low-concentration silane polymer solution. Therefore, a low-concentration silane polymer solution can be applied to a substrate twice or more so as to form a silicon film having a desired thickness. Thus, by repeating each of the application process and the heating process two or more times, the fine pattern of the substrate can be even more satisfactorily embedded with the silicon film.

After applying the silane polymer solution to the substrate to form a coating film, heat treatment may be performed to remove low boiling point components such as the solvent and the like. The heat treatment may be performed in a temperature range lower than that of the heating in a heating process to be described later, for example, in a range of 100 to 200 degrees C.

<Heating Process>

In the heating process, the coating film is heated. Accordingly, the coating film (a silane polymer film) can be converted to a silicon film.

Heating conditions are not particularly limited, and conditions conventionally used for forming a silicon film using a silane polymer may be adopted. For example, when forming an amorphous silicon film, the coating film may be heated at 300 to 550 degrees C. (preferably 350 to 500 degrees C.) for 30 seconds to 300 minutes.

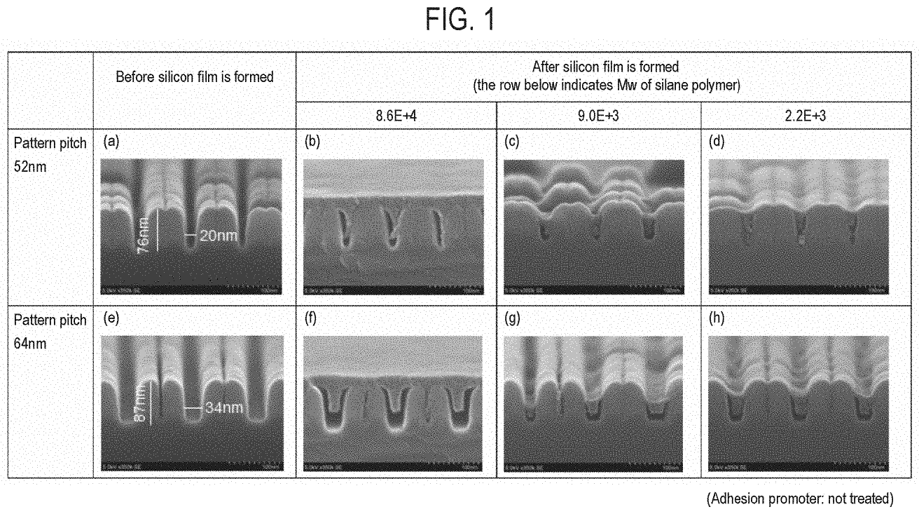

When converting a silane polymer film into a silicon film, the film tends to shrink. In the related art, such film shrinkage has been an obstacle in embedding a fine surface pattern with a silicon film. Specifically, due to the shrinkage of the film, a gap is formed between the fine pattern and the silicon film (refer to (b) to (d) of FIG. 1 and (f) to (h) of FIG. 1; a gap is formed between a wall and a bottom of each fine pattern and a silicon film). In contrast, prior to the formation of the silicon film, according to the silicon film forming method of the present disclosure in which surface treatment with an adhesion promoter is performed, a silicon film with good pattern embedding property can be formed even for a fine pattern including a narrow groove having a width of 30 nm or less or 20 nm or less. In addition, according to the method of forming a silicon film in accordance with an aspect of the present disclosure using a specific mixed solvent, a silicon film having a desired thickness can be formed by using silane polymers having a wide range of molecular sizes. In an embodiment, the formed silicon film is 0.5 nm to 100 nm. The thickness of the silicon film is preferably 80 nm or less, more preferably 50 nm or less, and still more preferably 40 nm or less, 30 nm or less, 20 nm or less, or 10 nm or less. A lower limit of the thickness of the silicon is not particularly limited, but may be typically 1 nm or more, 3 nm or more, or the like.

In the method of forming a silicon film of the present disclosure, in order to suppresses modification of an adhesion promoter, a silane polymer, and a silane polymer solution (including a photopolymerizable silane compound when combined), a series of processes is preferably performed under an atmosphere in which a concentration of oxygen or water is very low (preferably an atmosphere having an oxygen concentration of 1 ppm or less and a water concentration of 5 ppm or less). In an embodiment, a series of processes including the surface treatment process, the application process, and the heating process is performed in an atmosphere of an inert gas such as nitrogen, helium, argon, or the like. The series of processes may be performed in an atmosphere in which a reduction gas such as hydrogen is added to the inert gas.

### EXAMPLES

Hereinafter, a method of forming a silicon film according to an aspect of the present disclosure will be described in detail with reference to examples. However, the silicon film forming method disclosed herein is not limited to the examples shown below.

In the following description, “part” and “%” representing quantities mean “volume part” and “volume %”, respectively, unless otherwise specified. In addition, preparation of reagents, surface treatment with an adhesion promoter, application of a silane polymer solution, and heating of a silane polymer film were performed inside a glove box (a glove box apparatus with a “DBO-1KH Toku-OSC” gas circulation purifier manufactured by Miwa Seisakusho Co., Ltd.). An internal environment of the glove box was maintained at an oxygen concentration of 1 ppm or less and a water concentration of 5 ppm or less.

### Example 1

1. Examination of adhesion promoter
1.1. Confirmation of solvent wettability

### (1) Substrate Surface Treatment

As substrates, 2 cm square silicon substrates (free of a fine pattern) were prepared. In this evaluation, silicon substrates subjected to thermal oxidation (Th-Ox) treatment were used.
A 5 μL of a surface treatment agent was introduced into a glass bottle without a lid, and the glass bottle was placed inside a 300 mL airtight Teflon (registered trademark) container together with a substrate. Next, the airtight Teflon container was placed in a constant temperature bath, and surface treatment with a surface treatment agent was performed by setting an arrival temperature and a holding time and performing heating. In this evaluation, three types of surface treatment agents were used. Table 1 shows the surface treatment agents and the surface treatment conditions.

TABLE 1

| Surface treatment agent | | | | | | | | |
|---|---|---|---|---|---|---|---|---|
| | | Molecular | Boiling point | Surface treatment conditions * | | | | |
| | CAS No. | weight | (° C.) | 1 | 2 | 3 | 4 | 5 |
| Vinyltrimethoxysilane | 2768-02-7 | 148.23 | 123 | — | 60° C. | 80° C. | 100° C. | — |
| 3-aminopropyltrimethoxysilane | 13822-56-5 | 179.29 | 215 | — | 60° C. | 80° C. | 100° C. | 120° C. |
| Triethoxysilane | 998-30-1 | 164.28 | 134 | 40° C. | 60° C. | — | 100° C. | — |

* Indicating arrival temperature of constant-temperature bath (all of holding periods of time are 10 minutes)

### (2) Solvent Wettability

A 10 μL of decahydronaphthalene as a solvent was dropped onto each of the substrates subjected to the surface treatment in (1) above. Then, the solvent wettability was visually observed immediately after the dropping and 5 minutes after the dropping. In addition, for comparative reference, solvent wettability was also visually observed on reference substrates, which were not subjected to the surface treatment with the surface treatment agent.
As a result, it was confirmed that, compared with the substrate that was not subjected to the surface treatment with a surface treatment agent, the solvent wettability of the substrates subjected to the surface treatment with the surface treatment agent was somewhat reduced regardless of the type of the surface treatment agent and the surface treatment conditions. Among the substrates subjected to the surface treatment with the surface treatment agent, the substrates subjected to the surface treatment with vinyltrimethoxysilane or 3-aminopropyltrimethoxysilane were better in solvent wettability compared to the substrates subjected to the surface treatment with triethoxysilane.

### 1.2. Confirmation of Film Formation Property of Silicon Film

### (1) Preparation of Silane Polymer Solution

As a silane polymer, a silane polymer derived from cyclohexasilane was prepared. A 500 μL of cyclohexasilane monomer was introduced into a 6 mL glass bottle and irradiated with light while being stirred using a stirrer to prepare a silane polymer. By changing conditions of irradiation with the light (a wavelength, an output, and an irradiation time) for cyclohexasilane, multiple silane polymers having different weight average molecular weights (Mw; polystyrene-equivalent) were prepared. As the light source, a UV light source having wavelengths of 313 nm and 365 nm was used. In this evaluation, a silane polymer having an Mw of about 27.000 was used.
At a room temperature, 20 parts of silane polymer was added to 80 parts of a solvent (a mixed solvent of cyclooctane:decahydronaphthalene=1:3 (volume ratio)), and the mixture was stirred to prepare a stock solution of a silane polymer solution.

(2) Application of Silane Polymer Solution to Substrate

After confirming the solvent wettability in 1.1. above, decahydronaphthalene on the substrates was wiped off and the substrates were dried to remove the same. Each of the obtained substrates was used for this evaluation. An 80 μL of a silane polymer solution was dropped onto the substrates using a micropipette and applied to the substrates by spin coating. The conditions for spin coating were main spinning: 500 rpm and 8 sec. Further, as the silane polymer solution, a diluted solution obtained by diluting a stock solution of the silane polymer solution prepared in (1) above to a silane polymer concentration of 2.5% was used. At the time of the dilution, the same solvent as that used for preparing the stock solution was used.

(3) Heating of Coating Film (Formation of Silicon Film)

After the spin coating, the coating film on each substrate was heated at 400 degrees C. for 15 minutes to form a silicon film.
As a result, the formation of a silicon film was not observed on the substrates subjected to the surface treatment with triethoxysilane. In contrast, it was observed that a silicon film could be formed on the substrates subjected to the surface treatment with vinyltrimethoxysilane or 3-aminopropyltrimethoxysilane. Specifically, the formation of the silicon film was confirmed on each of the substrates subjected to the surface treatment with vinyltrimethoxysilane at 80 degrees C. and 60 degrees C. Further, regarding the substrates subjected to the surface treatment using 3-aminopropyltrimethoxysilane, the formation of the silicon film was observed regardless of the surface treatment conditions.

### Example 2

### 2. Forming Silicon Film on Substrate Having Fine Pattern

2.1. Surface Treatment of Substrate with Adhesion Promoter
As substrates, 2 cm square silicon substrates (having a fine pattern) were prepared. In this evaluation, silicon substrates on which a fine pattern (pattern pitch: 52 nm) having a 20 nm wide groove was formed (see (a) in FIG. 1; hereinafter, also referred to as a “silicon substrate having a 52 nm pattern pitch”) and silicon substrates on which a fine pattern (pattern pitch: 64 nm) having a 34 nm wide groove was formed (see (e) in FIG. 1; hereinafter, also referred to as “silicon substrate having a 64 nm pattern pitch”) were used. In each of the substrates used, a bottom of the fine pattern was made of Si₃N₄, a top of the fine pattern was made of SiO₂, and an entire surface of the substrate including the fine pattern was coated with a silicon film (a thickness of 1.5 nm) formed through atomic layer deposition.
A 5 μL of an adhesion promoter was introduced into a glass bottle without a lid, and the glass bottle was placed inside a 300 mL airtight Teflon container together with the substrate. Next, the airtight Teflon container was placed in a constant-temperature bath, and surface treatment with an adhesion promoter was performed by setting the arrival temperature and the holding time and performing heating. In this evaluation, vinyltrimethoxysilane and 3-aminopropyltrimethoxysilane were used as adhesion promoters. The surface treatment conditions were the same as those described in 1.1. above (Table 1).
Also, for comparative reference, reference substrates whose surfaces were not treated with an adhesion promoter were also prepared.

### 2.2. Preparation of Silane Polymer Solution

In the same manner as 1.2. above, multiple silane polymers having different weight average molecular weights (Mw: polystyrene-equivalent) were prepared. In this evaluation, six types of silane polymers having an Mw in a range of about 650 to about 110.000 were used. At a room temperature, 20 parts of silane polymer were added to 80 parts of solvent and stirred to prepare a stock solution of a silane polymer solution. A composition of the solvent used in this evaluation is shown in Table 2, and a composition of the prepared silane polymer solution is shown in Table 3.

TABLE 2

| | | Single solvent | | Mixed solvent | |
|---|---|---|---|---|---|
| | | 1 | 2 | 1 | 2 |
| * Composition | Cyclooctane | 1 | 0 | 1 | 1 |
| | Decahydronaphthalene | 0 | 1 | 3 | 0.33 |

* Volume part

TABLE 3

| | Silane polymer solution* | | | | | |
|---|---|---|---|---|---|---|
| | 1 | 2 | 3 | 4 | 5 | 6 |
| Silane polymer | Mw6.5E+2 | Mw2.7E+4 | MW1.1E+5 | Mw2.2E+3 | Mw9.0E+3 | Mw8.6E+4 |
| Solvent | Mixed | Mixed | Single | Single | Mixed | Mixed |
| | solvent 1 | solvent 1 | solvent 1 | solvent 2 | solvent 2 | solvent 2 |

*Prepared by dissolving 20 parts of silane polymer in 80 parts of solvent

### 2.3. Application of Silane Polymer Solution to Substrate

A 160 μL of the silane polymer solution was dropped onto the substrates prepared in 2.1. above using a micropipette and applied to the substrates by spin coating. Conditions for spin coating were main spinning: 500 rpm and 8 sec. As the silane polymer solution, a diluted solution obtained by diluting the stock solution of the silane polymer solution prepared in 2.2. above to a silane polymer concentration of 2.5% was used. At the time of the dilution, the same solvent as that used for preparing the stock solution was used. For the substrates subjected to the surface treatment with the adhesion promoter, silane polymer solutions 1 to 3 were used as a stock solution. For the reference substrates not subjected to the surface treatment with the adhesion promoter, silane polymer solutions 4 to 6 were used as a stock solution.

### 2.4. Heating of Coating Film (Formation of Silicon Film)

After the spin coating, the coating film on each substrate to be processed was heated at 400 degrees C. for 15 minutes to form a silicon film.

Evaluation of Fine Pattern Embedding Property

For each substrate to be evaluated, a state of the silicon film was observed using SEM.

(1) Reference Substrate

FIG. 1 shows SEM photographs of reference substrates, which were not surface-treated with the adhesion promoter. Regarding each of the reference substrates which were not surface-treated with the adhesion promoter, it was confirmed that due to shrinkage of a silicon film, a gap was formed between a wall and a bottom of fine patterns ((b) to (d) and (f) to (h) of FIG. 1).

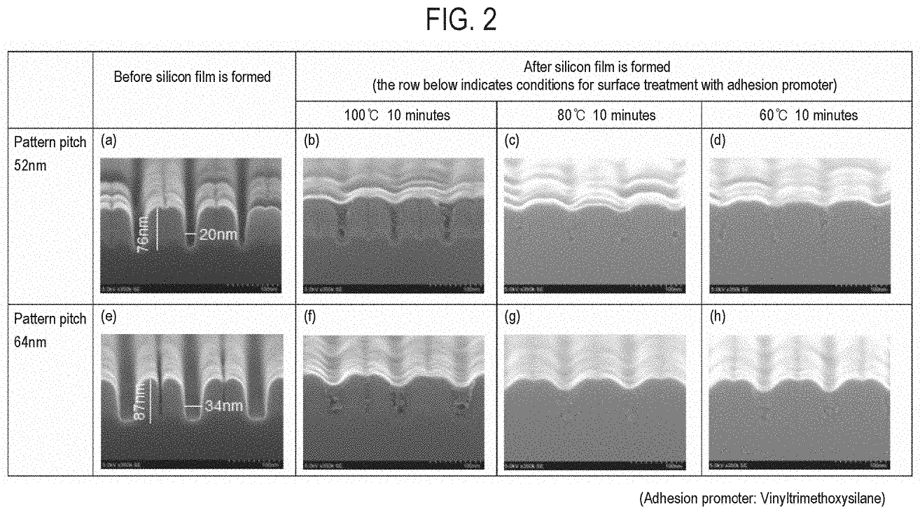

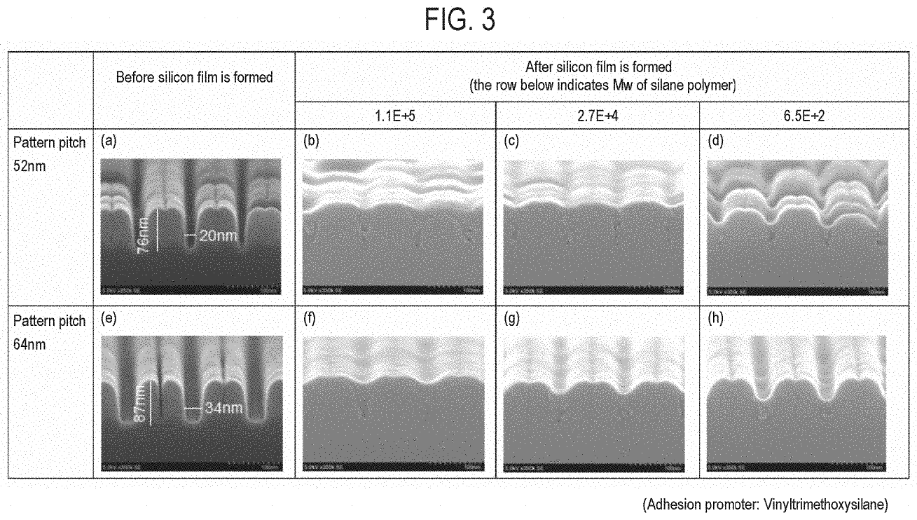

(2) Substrates Subjected to Surface Treatment with Vinyltrimethoxysilane SEM photographs of the substrates subjected to the surface treatment with vinyltrimethoxysilane are shown in FIG. 2 and FIG. 3. FIG. 2 shows silicon films formed using a silane polymer solution 2 on the substrates that were subjected to the surface treatment at 100 degrees C., 80 degrees C., and 60 degrees C. FIG. 3 shows silicon films formed using silane polymer solutions 1, 2, and 3 on each of the substrates that were subjected to the surface treatment at 60 degrees C. Regarding each of the substrates subjected to the surface treatment with vinyltrimethoxysilane, it was confirmed that no gap was formed between the formed silicon film and the wall and the bottom of the fine pattern and that the fine pattern was well embedded by the silicon film ((b) to (d) in FIG. 2, (f) to (h) in FIG. 2, (b) to (d) in FIG. 3, and (f) to (h) in FIG. 3).

(3) Substrates Subjected to Surface Treatment with 3-Aminopropyltrimethoxysilane

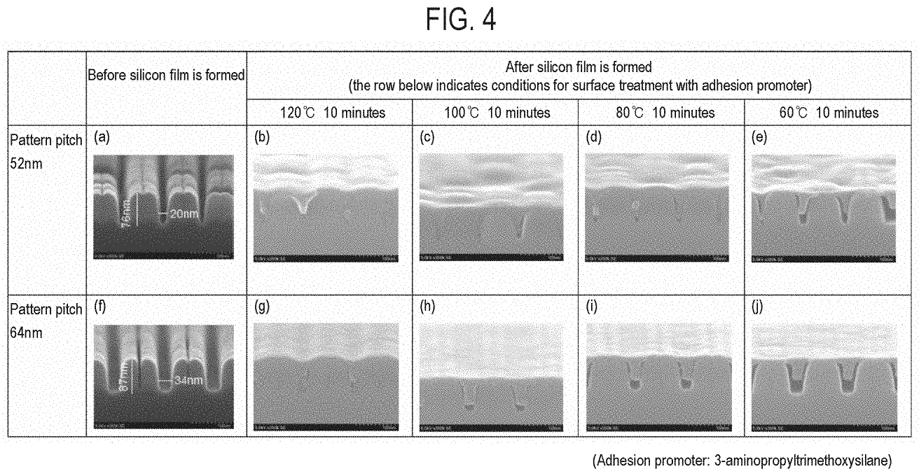

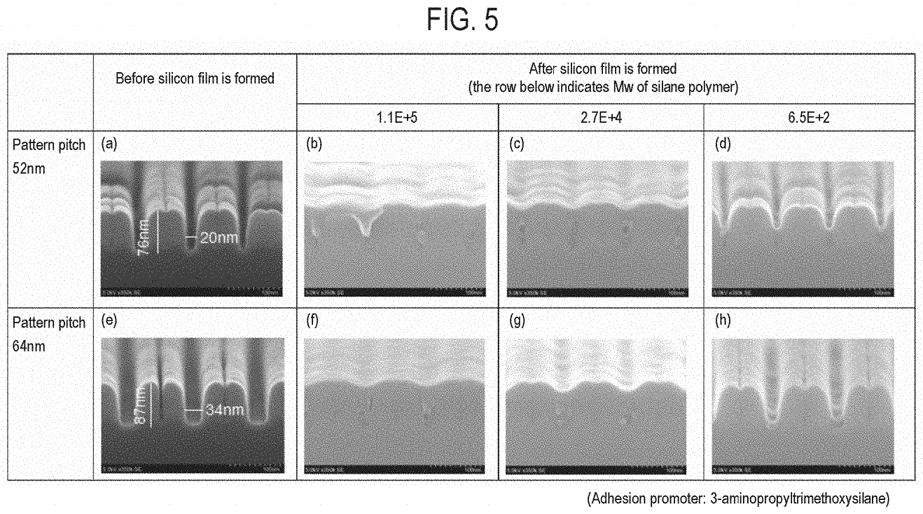

FIGS. 4 and 5 show SEM photographs of substrates subjected to the surface treatment with 3-aminopropyltrimethoxysilane. FIG. 4 shows silicon films formed using silane polymer solution 3 on the substrates that were subjected to the surface treatment at 120 degrees C. 100 degrees C., 80 degrees C., and 60 degrees C. FIG. 5 shows silicon films formed using silane polymer solutions 1, 2, and 3 on each of the substrates that were subjected to the surface treatment at 120 degrees C.
Regarding the substrates on which the surface treatment was performed with 3-aminopropyltrimethoxysilane, it was confirmed that the substrates that were subjected to the surface treatment at 120 degrees C. exhibited the best pattern embedding property, and that, in each of the substrates that were subjected to the surface treatment at 80 degrees C. and 60 degrees C. a gap was formed between a wall and a bottom of a fine pattern ((b) to (e) and (g) to (j) in FIG. 4). Regarding each of the substrates that were subjected to the surface treatment at 120 degrees C., it was confirmed that no gap was formed between a wall and a bottom of a fine pattern regardless of the Mw of the silane polymer, and the fine patterns were satisfactorily embedded with the silicon film ((b) to (d) in FIG. 5 and (f) to (h) in FIG. 5).
From the above, it was confirmed that when forming a silicon film on a substrate having a fine pattern, it is possible to form the silicon film with good pattern embedding property by performing surface treatment with the adhesion promoter on the substrate.

1-10. (canceled)

11. A method of forming a silicon film on a substrate having a fine pattern, the method comprising:
performing surface treatment with an adhesion promoter on the substrate having the fine pattern;
forming a coating film by applying a silane polymer solution to the substrate on which the surface treatment has been performed; and
heating the coating film.

12. The method of claim 11, wherein the fine pattern includes a groove.

13. The method of claim 12, wherein the groove has a width of 50 nm or less.

14. The method of claim 13, wherein the fine pattern includes a dummy gate pattern.

15. The method of claim 14, wherein the adhesion promoter is a silane compound represented by formula (1) below,
Si(X)ₘ₁(R¹)m₂(R²)₄₋ₘ₁₋ₘ₂ (1)
[In the formula, X represents a monovalent group including a functional group that contributes to bonding to the silane polymer,
R¹ represents a hydroxy group, an alkoxy group, or a halogen atom,
R² represents a hydrogen atom, an alkyl group, or an aryl group, and
each of m1 and m2 represents an integer of 1 to 3 satisfying a condition that a sum of m1 and m2 is 4 or less. When there are multiple Xs, the multiple Xs are the same as or different from each other, when there are multiple R¹s, the multiple R¹s are the same as or different from each other, and when there are multiple R²s, the multiple R²s are the same as or different from each other].

16. The method of claim 15, wherein X represents the monovalent group including the functional group selected from a group including a vinyl group, an amino group, an epoxy group, a mercapto group, a (meth)acrylic group, an isocyanate group, an imidazolyl group, a ureid group, a sulfide group, and an isocyanurate group.

17. The method of claim 16, wherein X represents the monovalent group including the vinyl group or the amino group.

18. The method of claim 17, wherein m1 is 1 and m2 is 3.

19. The method of claim 18, wherein the adhesion promoter has a molecular weight of 400 or less.

20. The method of claim 19, wherein the surface treatment with the adhesion promoter is performed through vapor deposition.

21. The method of claim 15, wherein X represents the monovalent group including a vinyl group or an amino group.

22. The method of claim 15, wherein m1 is 1 and m2 is 3.

23. The method of claim 11, wherein the fine pattern includes a dummy gate pattern.

24. The method of claim 11, wherein the adhesion promoter is a silane compound represented by formula (1) below.
Si(X)ₘ₁(R¹)m₂(R²)₄₋ₘ₁₋ₘ₂ (1)
[In the formula, X represents a monovalent group including a functional group that contributes to bonding to the silane polymer,
R¹ represents a hydroxy group, an alkoxy group, or a halogen atom,
R² represents a hydrogen atom, an alkyl group, or an aryl group, and
each of m1 and m2 represents an integer of 1 to 3 satisfying a condition that a sum of m1 and m2 is 4 or less. When there are multiple Xs, the multiple Xs are the same as or different from each other, when there are multiple R¹s, the multiple R¹s are the same as or different from each other, and when there are multiple R²s, the multiple R²s are the same as or different from each other].

25. The method claim 11, wherein the adhesion promoter has a molecular weight of 400 or less.

26. The method of claim 11, wherein the surface treatment with the adhesion promoter is performed through vapor deposition.
